(19) United States
(12) Patent Application Publication
(10) Pub. No.: US 2015/0270155 A1
(43) Pub. Date: Sep. 24, 2015

(54) ACCOMMODATING DEVICE FOR ACCOMMODATION AND MOUNTING OF A WAFER

(71) Applicant: EV GROUP INC., Tempe, AZ (US)

(72) Inventors: Spencer Hochstetler, Kingsport, TN (US); Richard Dalton Peters, Westfield, IN (US); Travis Acra, Ingalls, IN (US)

(73) Assignee: EV GROUP INC., Tempe, AZ (US)

(21) Appl. No.: 14/435,961

(22) PCT Filed: Nov. 21, 2012
(86) PCT No.: PCT/US12/66204

§ 371 Date: Apr. 15, 2015

(51) Int. Cl. H01L 21/687; H01L 21/67

(52) U.S. Cl. CPC H01L 21/68735; H01L 21/6704

(57) ABSTRACT

The present invention relates to an accommodating device for accommodation and mounting of a wafer for application of a fluid to a top of the wafer with the following features: a revolving ring section with: d) a revolving upper edge, e) a revolving recess and f) a circumferential wall running from the upper edge to the recess, a contact plane (A) arranged within the ring section for the accommodation of the wafer on a contact surface of the wafer, wherein the ring section by means of accommodation of the wafer forms with said wafer an accommodating space for accommodation of the fluid.

The present invention was made pursuant to a joint research agreement between Eastman Chemical Company and EV Group, Inc. in effect prior to the date the invention was made.

### FIELD OF THE INVENTION

The present invention relates to an accommodating device for accommodation and mounting of a wafer for processing the wafer in accordance with claim 1.

### BACKGROUND OF THE INVENTION

In the semiconductor industry various types of accommodating devices are used, which are also referred to as sample holders or chucks. Depending on the respective application process there are various sample holders, which can be heated over the entire surface or locally, have varying forms and sizes and are based on different holding principles. The most frequently used method for fixing a wafer to an accommodating device consists in the creation of a vacuum in structures on the mounting surface of the accommodating device. Frequently the object of the chucks consists among other things of sufficiently fixing the wafers during rotation.

During some types of wafer processing it is desirable to apply a predetermined fluid volume on the top of the wafer, but to prevent the fluid from coming into contact with the rear of the wafer as far as possible. On the one hand the fluid itself can contaminate the rear; on the other hand a contamination of the rear is conceivable through products which are transported by the fluid to the rear as well as through reaction products. It is also often desirable to have a precise and rapidly reacting control of the heating rate and the spatial uniformity of the temperature of the fluid which is applied to the top of the wafer. Because vacuum mounting devices touch a rather large region of the surface of the rear of the wafer lying on top of them, they can act as a heat sink. This in turn can slow down the heating rate of the fluid on top of the wafer. In addition, the regions of the wafer rear that are in contact with the vacuum mounting device cause the fluid that covers the wafer to be cooler in the corresponding contact regions than the fluid which faces the rear of the wafer, which is not in contact with the mounting device. Both the slower heating rate of the fluid regions opposite the touched regions of the wafer and the spatial temperature uniformity of the fluid on the wafer are often undesirable for a plurality of upper side wafer processes such as for example the removal of photoresist, etching, the removal of particles and similar processes.

One problem that is found both in the pin and vacuum mounting devices is the fact that when a fixed fluid volume is poured on the wafer surface, the fluid can flow down from the surface of the wafer. During the wafer processing this can lead to a decrease in the fluid thickness on at least a portion of the wafer, and the processing steps can be negatively influenced. For example if there is a decrease in fluid thickness during the removal of photoresist, there is a possibility that the photoresist will only be partially removed. In some cases the draining off of fluid from the top of the wafer can result in dry areas on the wafer, which can cause heat concentration points in regions of the wafer after the application of heat during the photoresist removal. This in turn can hamper the removal of photoresist during finishing processes or otherwise affect the quality of the process.

Therefore the problem addressed by the present invention is that of specifying an accommodating device with which an improved application of fluid with respect to temperature and/or fluid distribution is made possible while simultaneously preventing to the best of one's ability the application of fluid on sides of the wafer that are not supposed to have fluid applied to them.

### SUMMARY OF THE INVENTION

This problem is solved with the features of claim 1. Advantageous developments of the invention are specified in the subsidiary claims. Also, all combinations of at least two features cited in the description, the claims and/or drawings also fall within the scope of the invention. In the case of value ranges, those values lying within the named limits should also be disclosed as limits and can be claimed in any combination.

The present invention is based on the provision of an accommodating device especially with a specially formed or contoured ring section adapted to the wafer to be accommodated, in particular a circumferentially enclosed ring section which together with the accommodated wafer forms an accommodating space for the fluid to be applied on the wafer. In accordance with the invention the wafer can be accommodated within the ring section, wherein the word “within” means within the interior of the ring. The accommodating space thus formed is in particular open upward and is tightly sealed downward. The sealing takes place in accordance with the invention in particular at an inner circumference of the ring section, preferably at a circumferential edge and/or at a recess and/or at a mounting surface for the accommodation of the wafer. The mounting surface is in the process in particular only in contact with a small, in particular annular, surface section of a contact surface of the wafer (effective contact surface).

The ring section and/or the accommodating device are in particular at least predominantly annular, wherein the accommodating space is preferably constructed concentrically to the ring section. The incorporation of vacuum suction paths in the mounting surface in order to fix the wafer by means of low pressure would be conceivable. However, the mounting surfaces can also exhibit other fixations. For example, the use of electrostatic fixing elements, adhesive elements, clamping, surface grinding or the like are conceivable.

The invention describes in other words or in an alternative formulation a wafer support device to be used in single wafer processing applications which permits faster heating rates for fluids which are applied to the top of a wafer which is in contact with the mounting device and moreover improves the spatial uniformity of the fluid temperatures. It contains in addition a medium which holds a significant portion of an emitted fluid volume on top of the wafer, as a result of which the performance of the wafer processing can be increased, which otherwise could be decreased through the draining off of fluid from the top of the wafer.

The present invention solves the above described problems and permits both a slow and a rapid wafer rotation during a plurality of different wafer processing steps. The wafer mounting device can be constructed in such a way that it supports typical wafer shapes and sizes that are found in the fields of semi-conductors, micro-electromechanical components, light-emitting diodes, photovoltaics, wafer level packaging and in other similar fields. The invention permits in addition temperature monitoring on the top and rear of the wafer.

One significant advantage of the invention is the possibility of being able to cover a wafer with a greater fluid volume than is possible with a common vacuum mounting device or a pin mounting device which can aid in the removal of thick dry film photoresist. In certain preferred embodiments, the invention is in particular constructed in such a way that fluid thicknesses of more than 0.1 mm, more than 1.0 mm, more than 1.5 mm, or even up to 5 mm can be accommodated on the wafer. In alternative less preferred embodiments, the invention is constructed in such a way that fluid thicknesses of more than 10 mm or even more than 15 mm can be accommodated on the wafer. The dimensions of the mounting device are preferably selected in accordance with the invention in such a way that fluid volumes can be accommodated which permit a thickness of the fluid on the wafer of more than 0.1 mm, more than 1.0 mm, with more than 1.5 mm, or even up to 5 mm. In less preferred embodiments, the dimensions of the mounting device are selected in accordance with the invention in such a way that fluid volumes can be accommodated which permit a thickness of the fluid on the wafer of more than 10 mm, or even more than 15 mm in normal direction.

In accordance with an advantageous embodiment of the invention provision is made that the circumferential wall is contoured in accordance with a circumferential edge of the wafer. As a result of this, on the one hand an optimum alignment of the wafer relative to the accommodating device is ensured. On the other hand a sealing contact on the inner circumference of the ring section is made possible. The wafer can be constructed at least predominantly annular (with an alignment notch or a flat section). In this case not only is an alignment along the wafer necessary, but rather also in rotational direction.

A further inventive measure in accordance with an embodiment of the invention consists in the fact that the accommodating device exhibits an overflow plane differing from the contact plane formed by the upper edge, in particular running parallel to the contact plane. As a result of this a perfect contact and mounting of the wafer and a defined accommodating space volume are made possible. Simultaneously the accommodating device is easier to handle.

In the process it is particularly advantageous if the distance between the contact plane and the overflow plane is greater than the thickness of the wafer to be accommodated.

In accordance with a further advantageous embodiment of the present invention provision is made that the accommodating device exhibits an accommodation opening for the accommodation of the wafer formed by the upper edge and the circumferential wall. Hence the wafer can be efficiently accommodated and the fluid can simultaneously be supplied through the accommodation opening.

By having the accommodating device exhibit a mounting surface formed at least partially by the circumferential wall and/or by the recess or by at least an accommodating projection provided on the recess, the in particular sealing, mounting of the wafer on the accommodating device is made possible in a manner that is easy to handle. In accordance with the invention it is in particular conceivable to use a corresponding, in particular separate, sealing component in order to ensure the seal tightness between the wafer and mounting surface. In the process it is preferably a sealing ring.

Another idea in accordance with the invention consists in having the mounting surface less than 50% of the contact surface, in particular less than 25% of the contact surface, preferably less than 10% of the contact surface. Thus the heat transfer to the predominantly effective contact surface between the wafer and the accommodating device becomes more uniform so that there are slight heat fluctuations/differences along the wafer surface. Correspondingly, the wafer deforms less. Correspondingly, a material with optimum thermal conductivity is selected, preferably with the lowest possible thermal conductivity in order to decrease the convective heat transfer or to prevent it as far as possible.

The stability, in particular rigidity of the accommodating device is improved in accordance with the invention as a result of the fact that contact elements adjoining the recess are provided, in particular being provided in the form of a brace, preferably in a center of the accommodating device, even more preferably being radial, converging, contact elements.

If at least one projection is provided on the circumferential wall for fixation of the wafer in a rotational direction, a rotation of the wafer is made possible in easy and secure fashion.

The efficiency to clean the surface of the wafer can extensively be increased if additional apparatus are used to extend one of the disclosed embodiments.

A first extension would be a mechanical brush that contacts the surface of the wafer while the wafer is rotated. The brush can have any shape but will have most preferably a cylindrical shape. The cylindrical axis of the brush is parallel to the surface of the wafer. In case of a flat, rotational symmetric brush, the rotation axis is always normal to the wafer surface. In case of a flat, full area brush, the symmetrical axis of the brush even coincides with the normal symmetry axis of the wafer (suppose the wafer has no notch or flat, to have full rotational symmetry). In case of a flat, area brush that is smaller than the wafer, the brush can perform translational movement around the wafer. The brush itself can always rotate around its symmetrical axis.

A second extension would be a nozzle that implies a gas and/or liquid onto the surface of the wafer. The pressure and/or the velocity of the gas and/or liquid can be controlled precisely using external hardware and/or software controller. Moreover, the angle between the normal to the wafer and the jet of gas and/or fluid from the nozzle can be adjusted.

A third extension would be a sonic device, most likely a megasonic device that contacts at least the liquid wetting the wafer and/or the surface of the wafer. The megasonic device is either shaped like a pie or is a full area device.

All extensions can be used before, while and after the wetting of the wafer surface to improve and speed up cleaning of the wafer surface.

### BRIEF DESCRIPTION OF THE DRAWINGS

Additional advantages, features and details of the invention arise from the description of preferred exemplary embodiments as well as with the help of the drawings. The figures show the following:

FIG. 1a a view of a first embodiment of the inventive accommodating device,

FIG. 1b the accommodating device according to FIG. 1a with mounted wafer in a cutout partial lateral view along line of intersection A-A from FIG. 1a,

FIG. 2a a view of a second embodiment of the inventive accommodating device,

FIG. 2b the accommodating device according to FIG. 1a with mounted wafer in a cutout partial lateral view along line of intersection B-B from FIG. 2a,

FIG. 3a a view of a third embodiment of the inventive accommodating device,

FIG. 3b the accommodating device according to FIG. 1a with mounted wafer in a cutout partial lateral view along line of intersection C-C from FIG. 3a,

FIG. 4a a cutout partial lateral view of a fourth embodiment of the inventive accommodating device and

FIG. 4b the accommodating device according to FIG. 4a with mounted wafer in a cutout partial lateral view along line of intersection D-D from FIG. 4a.

### DETAILED DESCRIPTION OF THE PREFERRED EMBODIMENTS

In the figures identical components or components fulfilling the same function are marked with the same reference number.

The figures show different embodiments of an accommodating device 1 for accommodation and mounting of a wafer 3. The accommodation of the wafer 3 takes place by means of contact of a contact surface 3a of the wafer 3 on a mounting surface 2, 2′, 2″, 2″′, for example by a robot arm not shown in the figure which takes the wafer 3 from a wafer stack or a cassette and places it on the mounting surface 2.

An at least predominantly annular ring section 4 has at least two planes differing from one another, namely a contact plane A, upon which the wafer 3 is accommodated and if necessary fixed. In the process provision can be made that only a part of the contact surface 3a of the wafer 3, in particular a preferably annular, circumferential wall is touched (contact surface between wafer 3 and accommodating device 1).

Rear borders around recesses or flattened places which could be present in the wafer, are considered to be borders and would in particular likewise touch contact plane A. A circumferential edge 3k of the wafer 3 can in particular be in contact with a circumferential wall 7. The circumferential wall 7 can run orthogonally to contact plane A of the wafer 3 or at an angle relative to the wafer principal plane (contact surface 3a). A circular ring diameter B₁ of the circumferential wall 7 about the height of contact plane A is greater than or equal to a wafer diameter of the wafer 3, while an inside diameter B₂ of the ring section 4 is less than the wafer diameter. This applies analogously for correspondingly contoured embodiments, in particular a flat or notch or in the event of a non-annular design of the wafer 3. Therefore, the circular ring diameter B₁ preferably has a wafer diameter determined in the industry standard of 1″, 2″, 3″, 4″, 5″, 6′, 8″, 12″ or 18″. However, the circular ring diameter B₁ can also have a diameter deviating from this industry standard.

The second plane (overflow plane C) can terminate flush with a top 3o of the wafer surface or preferably protrude beyond it so that a fluid 9 on the wafer 3 can be accommodated without said fluid running extensively over the accommodating device 1. The fluid 9 is accommodated in an accommodating space 8 formed by the wafer 3 and the ring section 4, wherein the fluid 9 can be supplied via an accommodation opening 10 (thus from above) to the accommodating space 8 by means of a (not shown in the figure) dispensing device. The contact of the wafer 3 occurs not only on the recess 6, but rather in particular additionally on contact elements 12, which join the recess 6 radially or in a star pattern from a center of the accommodating device 1. In the process it is advantageous if between three and nine, preferably six, accommodation elements 12 are provided so that the contact surface 3a of the wafer 3 is exposed at least primarily and hence the least heat dissipation possible occurs via the accommodating device 1. In special embodiments the contact elements 12 can also be located beneath the recess 6, so that its surface does not come into contact with the wafer and hence, in accordance with the invention, a further thermal insulation takes place.

A distance D between contact plane A and the overflow plane C denotes the separation distance between the first and second plane (contact plane A and overflow plane C) and behaves proportionally to the fluid volume which can be accommodated by the accommodating device 1 in the accommodating space 8. The volume of the wafer 3 with the thickness d is in this connection to be deducted. The distance D is in particular selected greater than the thickness d of the wafer 3.

The contact plane A is formed by the mounting surface 2, 2′, 2″, 2″′. In addition the ring section exhibits a recess 6 which joins the circumferential wall 7. The overflow plane C on the other hand is formed by an upper edge 5 joining on the opposing end of the circumferential wall, wherein the circumferential wall 7 can have a rounded transition to the upper edge 5.

A radial formation (not shown in the figure) pointing in the direction of the wafer 3, in particular in the region of the circumferential wall 7, can hold the wafer in rotation in such a way that its speed conforms to the speed of the accommodating device 1, thus the wafer 3 does not shift in the accommodating device 1.

The accommodating device 1 can be made at least partially, preferably predominantly, of polymers, metals, ceramics or other materials or material combinations. Some surfaces, in particular those surfaces that can come into contact with processing fluids, can be coated in such a way that they are chemical resistant or that their surface energy is altered. Individual components of the accommodating device 1 can be composed of a number of these materials. As a result it is possible to use components with defined physical and/or chemical properties that are optimally adapted to the system. For example, through the combination of different materials the thermal conductivity and with it the transfer of heat can be minimized.

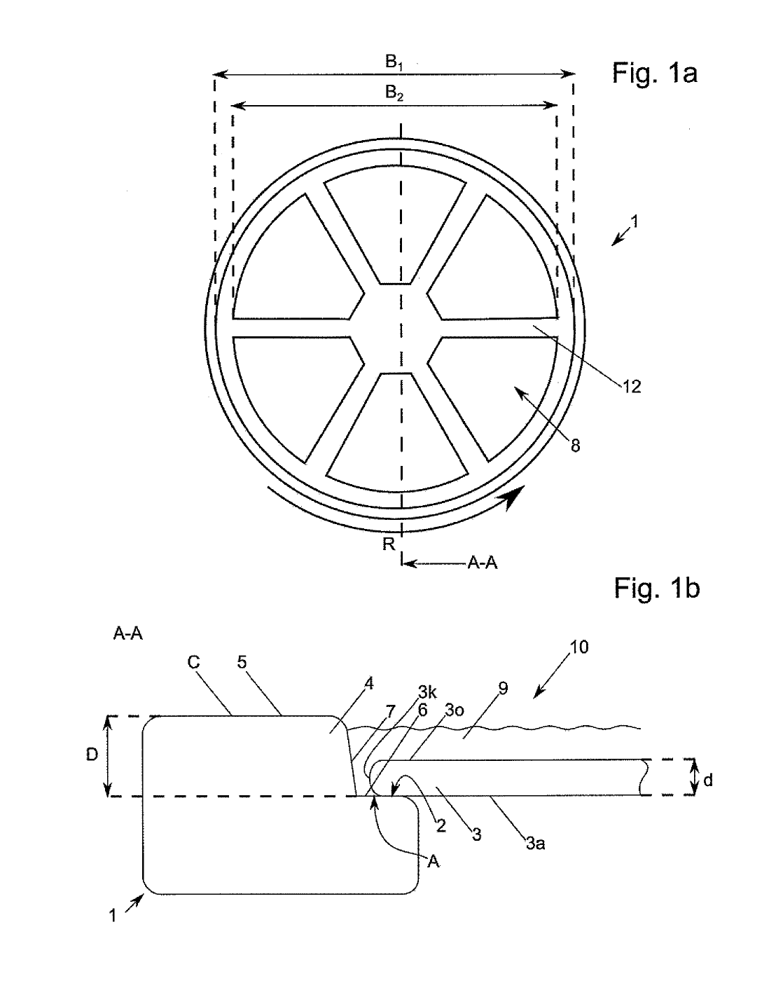

The singularity of a first embodiment of the invention according to FIGS. 1a and 1b lies in the fact that the accommodating device 1 here comprises exactly two planes (contact plane A and overflow plane C). In this embodiment contact plane A is formed by the recess 6. Hence this embodiment of the invention can easily be produced cost-effectively.

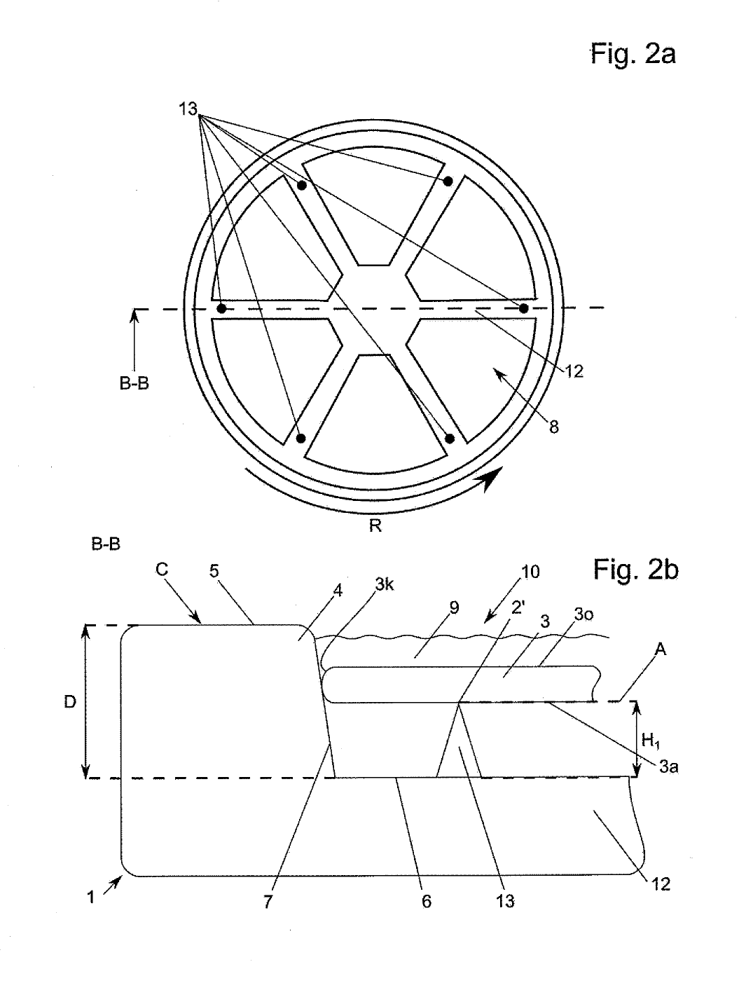

FIGS. 2a and 2b show a second embodiment of the present invention. This embodiment has the feature that the contact plane A is defined by tops, in particular spires, of at least three, preferably (here) six projections 13 (support elements) protruding from the recess 6. The support elements are preferably constructed as conically shaped pins. The wafer 3 is arranged aligned on the support elements. Hence this embodiment exhibits exactly three planes (contact plane A, overflow plane C and defined by the recess 6). The projections 13 exhibit a height H₁ which in total with the thickness d of the wafer 3 is less than the distance D.

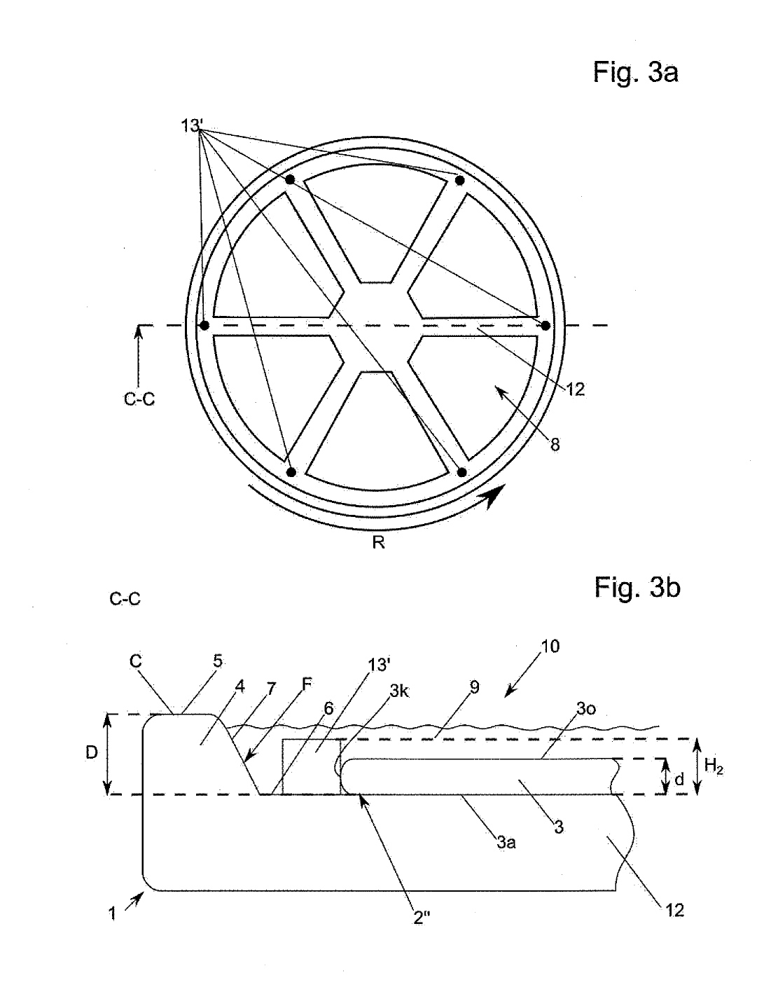

FIGS. 3a and 3b show a third and preferred embodiment. In this embodiment the contact plane A is formed by the recess 6, as with the first embodiment. The third embodiment however, exhibits the special feature that at least three, preferably (here) six projections 13′ protruding from the recess 6 are arranged distributed concentrically on the circumference. These are used to position the wafer 3 vis-à-vis the accommodating device 1, in particular by touching the circumferential edge 3k of the wafer 3. The projections 13′ can be fixed in their position or can be mounted off-center, so that the inside dimension formed by them can be adjusted. The projections 13′ exhibit a height H₂ which is in particular greater than the thickness d of the wafer 3 and/or less than the distance D.

A radial formation pointing in the direction of the wafer 3 on at least one of the projections 13′ can hold the wafer 3 in rotation so that its speed conforms to the speed of the accommodating device 1. Instead of a formation, one of the projections 13′ can also assume the function by shifting said projection radially inward, that is, in the direction of the wafer 3 after the wafer 3 is accommodated.

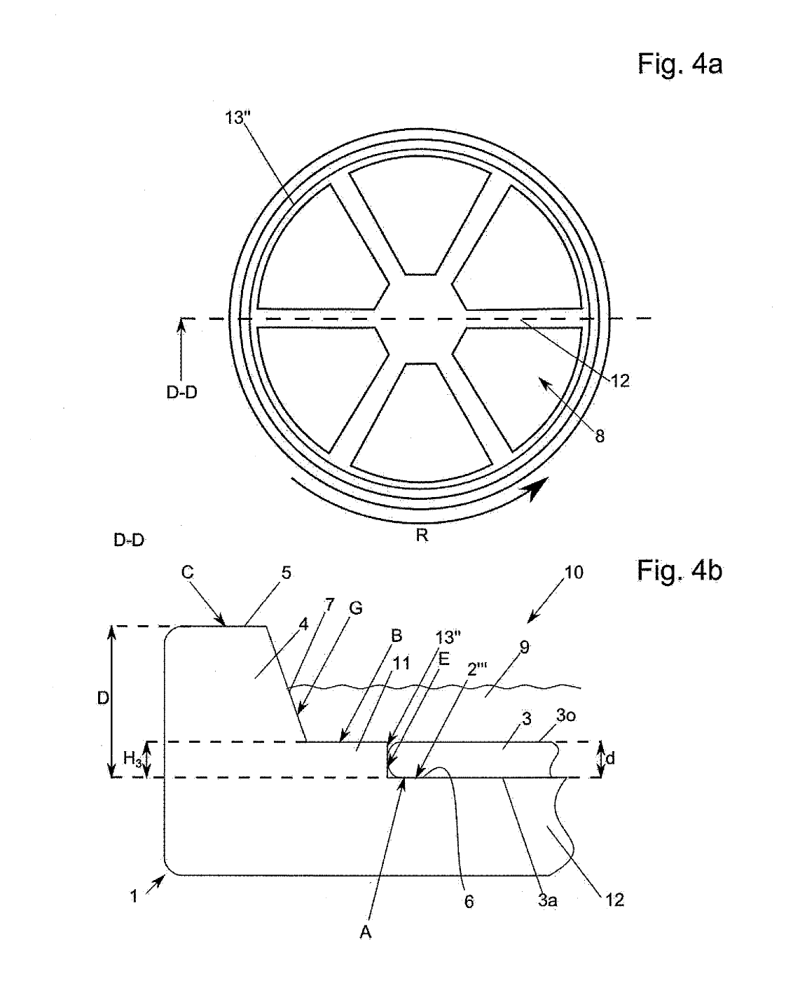

A fourth and likewise preferred embodiment can be seen in FIGS. 4a and 4b. This embodiment corresponds essentially to the third embodiment with the difference that the projections 13″ here are arranged on the transition of the circumferential wall 7 to the recess 6, in particular as formation(s) of the ring section 4. Preferably the projections are constructed as revolving tiers. The projections 13″ exhibit a height H₃ which in particular is approximately equal to the thickness d of the wafer 3 and/or less than the distance D.

Although all previously depicted embodiments are radial symmetric, it is obvious that embodiments can have an arbitrary shape, e.g. can be rectangular. Therefore, rectangular embodiments that have the same functional features shall also be disclosed.

### REFERENCE LIST

1 Accommodating device
2, 2′, 2″, 2″′ Mounting surface
3 Wafer
3a Contact surface
3k Circumferential edge
3o Top
4 Ring section
5 Upper edge
6 Recess
7 Circumferential wall
8 Accommodating space
9 Fluid
10 Accommodation opening
11 Accommodating projection
12 Contact elements
13, 13′, 13″ Projections
d Wafer thickness
D Distance
A Contact plane
C Overflow plane
R Rotational direction
B₁ Circular diameter
B₂ Inside diameter
H₁, H₂, H₃ Heights

1. An accommodating device for accommodation and mounting of a wafer for application of fluid to a top of the wafer with the following features:
a revolving ring section with:
a) a revolving upper edge,
b) a revolving recess and
c) a circumferential wall running from the upper edge to the recess,
a contact plane (A) arranged within the ring section for the accommodation of the wafer on a contact surface of the wafer,
wherein the ring section by means of accommodation of the wafer forms with said wafer an accommodating space for accommodation of the fluid.

2. Accommodating device according to claim 1, characterized in that the circumferential wall is contoured in accordance with a circumferential edge of the wafer.

3. Accommodating device according to claim 1, characterized in that it exhibits an overflow plane (C) differing from the contact plane (A) formed by the upper edge, in particular running parallel to the contact plane (A).

4. Accommodating device according to claim 3, characterized in that the distance (D) between the contact plane (A) and the overflow plane (C) is greater than the thickness d of the wafer to be accommodated.

5. Accommodating device according claim 1, characterized in that it exhibits an accommodation opening formed by the upper edge and the circumferential wall for the accommodation of the wafer.

6. Accommodating device according to claim 1, characterized in that it exhibits a mounting surface formed at least partially by
the circumferential wall and/or
the recess or
at least one accommodating projection provided on the recess.

7. Accommodating device according to claim 6, characterized in that the mounting surface is constructed as less than 50% of the contact surface, in particular less than 25% of the contact surface, preferably less than 10% of the contact surface.

8. Accommodating device according to claim 1, characterized in that the ring section is constructed circumferentially enclosed.

9. Accommodating device according to claim 1, characterized in that contact elements are provided joining to the recess, in particular provided in the form of a brace, preferably converging in a center of the accommodating device converging.

10. Accommodating device according to claim 1, characterized in that at least one projection is provided on the circumferential wall for fixation of the wafer in a rotational direction (R).
